(19) United States
(12) Patent Application Publication
(10) Pub. No.: US 2026/0237445 A1
(43) Pub. Date: Aug. 13, 2026

(54) SENSE CIRCUIT AND NON-VOLATILE MEMORY STRUCTURE INCLUDING THE SENSE CIRCUIT

(71) Applicant: GlobalFoundries U.S. Inc., Malta, NY (US)

(72) Inventors: Vinay Bhat Soori, Bangaluru (IN); Akshay Sudhir Petkar, Bengaluru (IN); Rony Thomas Samuel, Kerala (IN)

(21) Appl. No.: 19/051,493

(22) Filed: Feb. 12, 2025

(51) Int. Cl. G11C 16/28

(52) U.S. Cl. CPC G11C 16/28

(57) ABSTRACT

A sense circuit includes: an comparator with inverting and non-inverting inputs connected to data and reference nodes, respectively; and different reference current sources connected to the data and reference nodes, respectively. A read operation of a bit cell includes pre-charging the data and reference nodes. Depending upon whether a threshold voltage (VT)-programmable transistor of the bit cell has a high or low VT, a bit cell current (Icell) will be low or high. Icell and a first reference current injected into the data node cause a data voltage (Vdata) at the inverting input to ramp up (if VT is high) or ramp down (if VT is low). A second reference current pulled out of the reference node causes a reference voltage (Vref) at the non-inverting input to ramp down (as opposed to remaining constant at the pre-charge voltage) but to a lesser extent than Vdata when VT is low.

### BACKGROUND

The present disclosure relates to non-volatile memory (NVM) structures and, more particularly, to embodiments of a sense circuit and of a NVM structure, such as an embedded flash (eFlash) memory structure, including the sense circuit.

Goals of modern integrated circuit (IC) design include, but are not limited to, reducing area, improving performance, and reducing power consumption. In NVM structures (e.g., eFlash memory structures) area consumption has been improved with each new technology node. However, read access time, which is a key performance parameter in NVM structures, has remained essentially the same (e.g., at approximately 20-25 nanoseconds (ns)).

### SUMMARY

Disclosed herein are embodiments of a sense circuit structure. Generally, disclosed embodiments of a sense circuit structure can include a comparator with an inverting input and a non-inverting input. The structure can further include a data node connected to the inverting input and a reference node connected to the non-inverting input. The structure can further include a first reference current source connected between a first positive supply voltage rail and the data node and a second reference current source connected between the reference node and a ground rail.

In some embodiments, the sense circuit structure can include comparator with an inverting input and a non-inverting input. The structure can further include a data node connected to the inverting input and a reference node connected to the non-inverting input. The structure can further include a first reference current source, which includes a P-type field effect transistor connected between a first positive supply voltage rail and the data node, and a second reference current source, which includes an N-type field effect transistor connected between the reference node and a ground rail. The structure can further include a sense circuit control signal generator. This sense circuit control signal generator can generate and output (i.e., can be configured to generate and output) a first control signal and a second control signal. Furthermore, a gate of the P-type field effect transistor can be connected to receive the first control signal and a gate of the N-type field effect transistor can be connected to receive the second control signal.

Also disclosed herein are embodiments of an NVM structure including such a sense circuit. More specifically, embodiments of an NVM structure can include: an array of bit cells arranged in columns and rows; bit lines for the columns, wherein all bit cells in a column are connected to a bit line for the column; a multiplexor having inputs connected to the bit lines and an output connected to a data line; and a sense circuit. The sense circuit can include a comparator with an inverting input and a non-inverting input. The sense circuit can also include a data node connected to the data line and the inverting input, and a reference node connected to the non-inverting input. The sense circuit can further include a first reference current source, which is connected between a first positive supply voltage rail and the data node, and a second reference current source, which is connected between the reference node and a ground rail.

It should be noted that all aspects, examples, and features of disclosed embodiments mentioned in the summary above can be combined in any technically possible way. That is, two or more aspects of any of the disclosed embodiments, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The present disclosure will be better understood from the following detailed description with reference to the drawings, which are not necessarily drawn to scale and in which:

FIG. 1 is a schematic diagram illustrating an embodiment of a non-volatile memory (NVM) structure including a sense circuit;

FIG. 2A is a schematic diagram generally illustrating disclosed embodiments of a sense circuit that can be incorporated into the NVM structure of FIG. 1;

FIG. 2B is a schematic diagram illustrating, in greater detail, one embodiment of a sense circuit that can be incorporated into the NVM structure of FIG. 1;

FIG. 3 is a table illustrating example relationships between different threshold voltages (VTs) of a VT-programmable transistor in a bit cell and other parameters (bit cell current, data voltage, and data output values) associated with the different VTs;

FIG. 4A is a graph illustrating operation of a conventional sense circuit;

FIG. 4B is a graph illustrating operation of disclosed embodiments of a sense circuit; and

FIG. 5 is a schematic diagram illustrating one example of a control signal generator that can be incorporated into the sense circuit of FIG. 2B.

### DETAILED DESCRIPTION

As mentioned above, goals of modern integrated circuit (IC) design include, but are not limited to, reducing area, improving performance, and reducing power consumption. In NVM structures (e.g., eFlash memory structures) area consumption has been improved with each new technology node. However, read access time, which is a key performance parameter in NVM structures, has remained essentially the same (e.g., at approximately 20-25 nanoseconds (ns)).

In view of the foregoing, disclosed herein are embodiments of a sense circuit and a NVM structure (e.g., an eFlash memory structure) including the sense circuit. The sense circuit can include a comparator (e.g., an operational amplifier) with an inverting input connected to a data node and with a non-inverting input connected to a reference node. The sense circuit can also include first and second reference current sources connected to the data and reference nodes, respectively. During a read operation of a selected bit cell (e.g., a selected threshold voltage (VT)-programmable transistor), the data and reference nodes can be pre-charged. Depending upon whether the VT-programmable transistor has been programmed so as to have a high VT (e.g., to store a bit value of 0) or erased so as to have a low VT (e.g., to store a bit value of 1), the bit cell current (Icell) through the selected bit cell will be relatively low or relatively high, respectively. As a result of Icell and a first reference current (Iref1) from the first current source being injected into the data node during the read operation, a data voltage (Vdata) at the inverting input of the comparator will either ramp up (if the VT-programmable transistor has a high VT) or ramp down (if the VT-programmable transistor has a low VT). As a result of a second reference current (Iref2) from the second current source (which is less than the Iref1) being pulled out of the reference node during the read operation, a reference voltage (Vref) at the non-inverting input of the comparator will ramp down (as opposed to staying constant at the pre-charge voltage) but to a lesser extent than Vdata when the VT-programmable transistor has a low VT. By causing Vref to ramp down instead of remaining constant at the pre-charge voltage, the sense time (tsense) (i.e., the time period between when the read operation is initiated and when the comparator can be enabled) can be reduced (e.g., by up to 50%) without risking read errors. Thus, the read access time (tacc) of the NVM structure that incorporates the sense circuit can also be reduced.

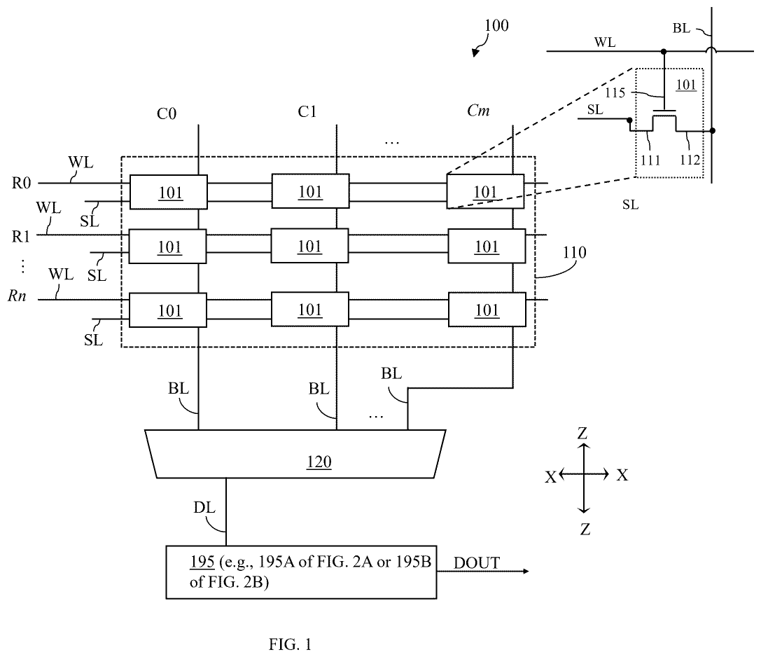

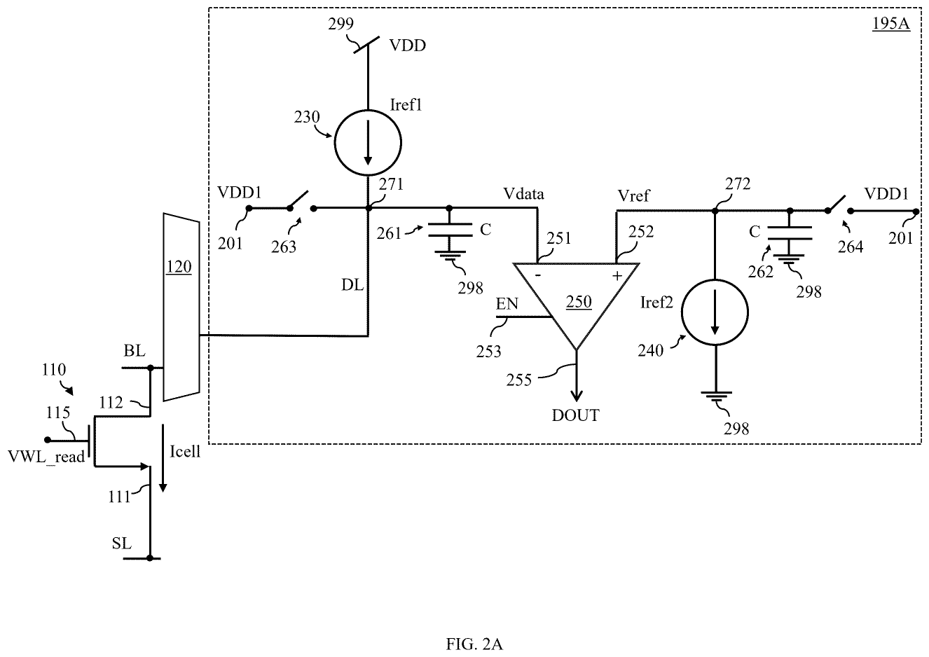

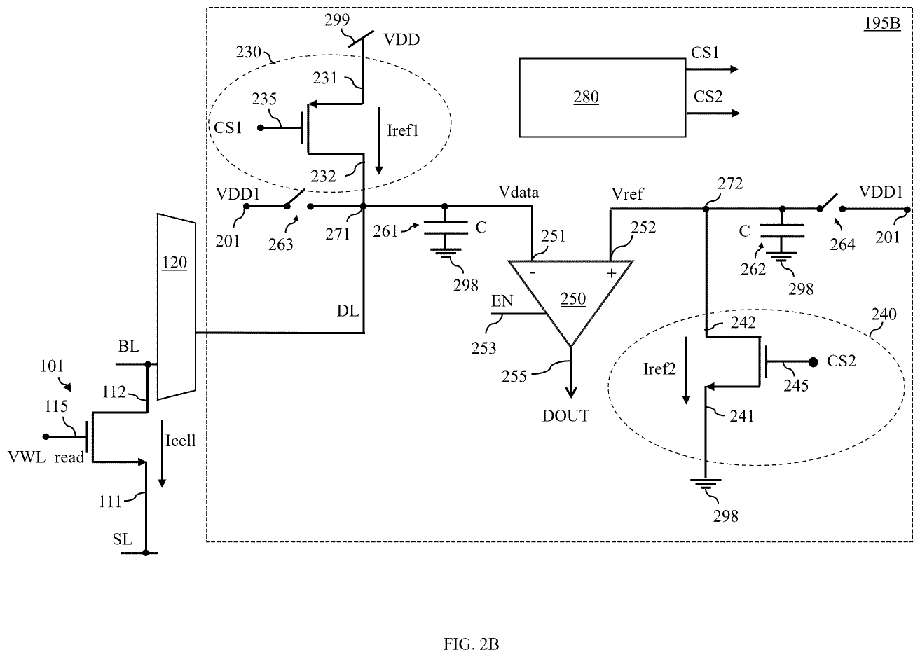

More particularly, FIG. 1 is a schematic diagram illustrating an embodiment of a non-volatile memory (NVM) structure 100 (e.g., an eFlash memory structure) including a sense circuit 195. FIG. 2A is a schematic diagram generally illustrating disclosed embodiments of a sense circuit 195A that can be incorporated into NVM structure 100 of FIG. 1 as sense circuit 195. FIG. 2B is a schematic diagram illustrating, in greater detail, one embodiment of a sense circuit 195B that can be incorporated into NVM structure 100 as sense circuit 195.

Referring to FIG. 1, NVM structure 100 can include an array 110 of bit cells 101. Bit cells 101 can be arranged in columns (e.g., see columns C0-Cm) and rows (e.g., see rows R0-Rn). For purposes of illustration, the columns are shown on the drawing sheet as being oriented in the Z-direction (i.e., from the top of the sheet toward the bottom) and the rows are shown on the sheet as being oriented in the X-direction (i.e., from the left-side of the sheet to the right-side). The orientation of the columns and rows is not intended to be limiting. For example, alternatively, the columns could be oriented in the X-direction and the rows could be oriented in the Z-direction. In any case, the columns can be essentially perpendicular to the rows with each bit cell 101 being located at an intersection between one column and one row.

Bit cells 101 can include, for example, threshold voltage (VT)-programmable N-type field effect transistors (VT-programmable NFETs), as illustrated. A VT-programmable NFET transistor can include N+source/drain regions 111-112 and a channel region (e.g., a P-channel region or an intrinsic channel region) positioned between the source/drain regions. A VT-programmable NFET can further include a gate 115 adjacent to the channel region. This gate 115 can be a multi-layered structure, which is configured so that the VT of the NFET is selectively variable depending on different voltage conditions applied to gate 115 and at least one of the source/drain regions 111-112. Specifically, due to the specific multi-layered configuration of gate 115 and the applied voltage conditions on gate 115 and source/drain regions 111-112, the VT of the NFET can be either programmed to be relatively high or erased to be relatively low. Thus, bit cell 101 can effectively function as a data storage node with a low Vt (also referred to herein as an erased state) representing a first stored bit value (e.g., a bit value of “1”) and with a high Vt (also referred to herein as a programmed state) representing a second stored bit value (e.g., a bit value of “0”).

Exemplary VT-programmable NFETs that can be incorporated into array 110 of NVM structure 100 as bit cells 101 can include, but are not limited to, charge trap field effect transistors (CTFETs), ferroelectric field effect transistors (FeFETs), and floating gate field effect transistors (FGFETs). The gates 115 of such VT-programmable FETs include different layers. For example, the gate 115 of a CTFET can include a gate dielectric layer on the channel region, a charge trap layer (e.g., a silicon nitride layer) on the gate dielectric layer, another gate dielectric layer on the charge trap layer, and a control gate layer (e.g., a metal gate layer) on the gate dielectric layer. Depending upon voltage conditions on the gate 115 and source/drain regions 111-112, electrons can move into the charge trap layer to increase the VT or move out of the charge trap layer to decrease the VT. Alternatively, the gate of a FeFET can include a gate dielectric layer on the channel region, a ferroelectric layer (e.g., a hafnium oxide layer or some other suitable ferroelectric layer) on the gate dielectric layer, and a control gate layer (e.g., a metal gate layer) on the ferroelectric layer. Depending upon voltage conditions on the gate 115 and source/drain regions 111-112, the direction of polarization vector of the ferroelectric layer can point away from the channel region such that electrons are repelled from the channel region to increase the VT or the direction of polarization vector of the ferroelectric layer can point toward the channel region such that electrons are attracted into the channel region to decrease the VT. Alternatively, the gate of a FGFET can include a gate dielectric layer on the channel region, a floating gate layer (e.g., a polysilicon layer) on the gate dielectric layer, another gate dielectric layer on the floating gate layer and a control gate layer (e.g., a metal gate layer) on the gate dielectric layer. Depending upon voltage conditions on the gate 115 and source/drain regions 111-112, electrons can move into the floating gate layer to increase the VT or move out of the floating gate layer to decrease the VT. Those skilled in the art will recognize that the voltage conditions on the gate 115 and source/drain regions 111-112 of a VT-programmable NFET of a bit cell 101 during a write operation (i.e., during a programming operation or an erasing operation) will vary depending upon the type of VT-programmable NFET (e.g., CTFET, FeFET, or FGFET) and the technology node at issue. Such voltage conditions are well known in the art. Thus, the details thereof have been omitted from this specification in order to allow the reader to focus on the salient aspects of the disclosed embodiments related to sense circuit 195.

In any case, those skilled in the art will recognize that, during a read operation using sense circuit 195 to determine the value of a bit stored in a selected bit cell, a bit cell current (Icell) flowing through the selected bit cell will vary depending upon whether the VT-programmable NFET of the selected bit cell is in the programmed state (e.g., a high VT and storing a bit value of 0) or in the erased state (e.g., a low VT and storing a bit value of 1). For example, Icell will be greater when the VT-programmable NFET of the selected bit cell is in the erased state as compared to when the VT-programmable NFET of the selected bit cell is in the programmed state. Furthermore, in some cases, Icell may vary depending upon the relative strength of the programmed or erased state. For example, when the VT-programmable NFET is in a strong erased state, it may exhibit a maximum Icell (Icell_max). When the VT-programmable NFET is in a weak erased state, it may exhibit a lower Icell (e.g., an Icell of ~0.5*Icell-max). When the VT-programmable NFET is in a weak programmed state, it may exhibit an even lower Icell (e.g., an Icell of ~0.1*Icell_max). When the VT-programmable NFET is in a strong programmed state, it may exhibit little to no Icell (e.g., an Icell of ~0.0 amperes (A)).

NVM structure 100 can further include additional circuitry to facilitate the above-described write operations (i.e., the programming or erasing operations) and read operations. This additional circuitry can include various voltage signal lines connected to the bit cells 101 in array 110. These voltage signal lines can include, for example, bit lines (BLs) for the columns C0-Cm, respectively, and word lines (WLs) and source lines (SL) for the rows R0-Rn, respectively. All bit cells 101 in each column can be electrically connected to a BL for that column and all bit cells 101 in each row can be electrically connected to a WL and a SL for that row. For example, within each VT-programmable NFET of each bit cell 101 in a given column and a given row: gate 115 can be electrically connected to the WL for the row; one source/drain region 111 can be electrically connected to the SL for the row; and the other source/drain region 112 can be electrically connected to the BL for the row. The additional circuitry can also include a controller and peripheral circuitry, which is electrically connected to the WLs, BLs, and optionally the SLs, which is in communication with the controller, and which is configured to apply appropriate voltage conditions onto the voltage signal lines in response to control signals from the controller in order to cause the NVM structure to perform memory operations (e.g., write or read operations directed to selected bit cells). Voltage signal lines, peripheral circuitry, and controllers for NVM structures are well known in the art. Thus, the details thereof have been omitted from this specification in order to allow the reader to focus on the salient aspects of the disclosed embodiments related to sense circuit 195.

The additional circuitry can also include one or more sense circuits 195. For example, as illustrated, the additional circuitry can include a sense circuit 195. Sense circuit 195 can be selectively connectable to any one of all the BLs of array 110 via a multiplexer (MUX) 120. That is, MUX 120 can include multiple inputs electrically connected to the BLs, respectively. MUX 120 can further include an output, which is electrically connected by a data line (DL) to sense circuit 195. During read operation (as discussed in greater detail below), MUX 120 can (e.g., in response to a BL select signal from the controller) selectively connect a BL (and thereby a selected bit cell connected thereto) to the DL and thereby to sense circuit 195. Alternatively, the BLs can be divided into groups with each group of BLs being connected by a corresponding multiplexer to a corresponding sense circuit (not shown). Alternatively, each BL can be directly connected to a corresponding sense circuit (not shown).

As mentioned above, FIGS. 2A and 2B are schematic diagrams illustrating disclosed embodiments of sense circuit 195A and 195B, respectively, that can be incorporated into NVM structure 100 of FIG. 1 as sense circuit 195. Referring to FIGS. 2A-2B, sense circuit 195A, 195B can include a data sensing section including a data node 271, a reference section including a reference node 272, and a comparator 250 (e.g., an operational amplifier or other device suitable for performing a comparator function). Comparator 250 can include: an inverting input 251, which is electrically connected to data node 271; a non-inverting input 252, which is electrically connected to reference node 272; and an output 255. Comparator 250 can be connected to receive a data voltage (Vdata) from data node 271 at inverting input 251 during a read operation and to concurrently receive a reference voltage (Vref) from reference node 272 at non-inverting input 252 during the read operation. Comparator 250 can further be configured (when enabled by an enable signal (EN) 253 during the read operation after a predetermined period of time, referred to herein as a sense time (tsense)) to compare Vdata to Vref and: (a) if Vdata is above Vref and a first predetermined voltage differential (Vdiff0) is detected, then a data output value (Dout) at output 255 will switch to a logic value of 0; and (b) if Vdata is below Vref and a second predetermined voltage differential (Vdiff1) is detected, then a Dout at output 255 will switch to a logic value of 1.

Vdiff0 and Vdiff1 are predetermined to minimize the likelihood of any read errors (i.e., a false Dout of 0 when the bit value stored in the selected bit cell is 1 or a false Dout of 1 when the bit value stored in the selected bit cell is a 0, respectively). It should be noted that, during the read operation, the time period between when the read operation is initiated and when the comparator is enabled is predetermined to ensure that the required Vdiff0 or Vdiff1 have sufficient time to develop and, thereby to ensure that read errors are avoided. This time period is referred to herein as the sense time (tsense) and it makes up a significant portion of the overall read access time (tacc)).

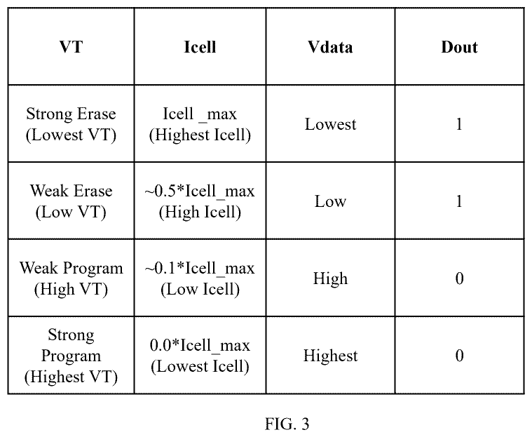

FIG. 3 is a table illustrating example relationships between different VTs of a VT-programmable transistor of a selected bit cell 101 and Icell values, Vdata values, and Dout values captured after tsense. As illustrated in FIG. 3, if the VT-programmable NFET of the selected bit cell 101 has a high or very high VT, Icell will be low, Vdata on data node 271 will be high, and Dout will be low. Contrarily, if the VT-programmable NFET of the selected bit cell 101 has a low or very low VT, Icell will be high, and Vdata on data node 271 will be low, and Dout will be high. Comparators configured to switch a data output value as a function of a voltage differential detected between input voltages received at inverting and non-inverting inputs are well known in the art. Thus, the details thereof have been omitted from the specification in order to allow the reader to focus on the salient aspects of the disclosed embodiments related to Vdata-to-Vref voltage differential development in a manner that allows tsense to be reduced (e.g., by up to 50%).

Referring again to FIGS. 2A-2B, the data sensing section of sense circuit 195A, 195B can further include a first reference current source 230. The first reference current source 230 can be electrically connected between a first positive supply voltage rail 299 at a first positive supply voltage (e.g., at VDD) and data node 271 and can generate (i.e., can be configured to generate) a first reference current (Iref1). Iref1 can, for example, be generated in response to a first control signal (CS1) and can be less than Icell_max. For example, in some embodiments, Iref1 can be generated in response to CS1 such that it is equal to approximately 0.2*Icell_max. Referring specifically to sense circuit 195B of FIG. 2B, in some embodiments, this first reference current source 230 can be a P-type field effect transistor (PFET). The PFET can include: P+ source/drain regions 231-232; an N-channel region or an intrinsic channel region between the P+ source/drain regions 231-232; and a gate 235 adjacent to the channel region. Gate 235 can be electrically connected to receive CS1 (e.g., from a control signal generator 280, discussed in greater detail below). Alternatively, any other now known or subsequently developed first reference current source could be employed. The data sensing section of sense circuit 195A, 195B can further include a first capacitor 261. First capacitor 261 can include: capacitor plates that are electrically connected to data node 271 and a ground rail 298; and a capacitor dielectric between the capacitor plates. The data sensing section of sense circuit 195A, 195B can further include a first switch 263, which is electrically connected between a second positive supply voltage rail 201 at a second positive supply voltage (VDD1) (which is equal to a desired pre-charge voltage (Vpre-charge)) and data node 271. Lastly, within data sensing section of sense circuit 195A, 195B, data node 271 can, during a read operation directed to a selected bit cell 101, be electrically connected to the BL that is electrically connected to that selected bit cell 101 (e.g., via DL and MUX 120).

The reference section of sense circuit 195A, 195B can further include a second reference current source 240. The second reference current source 240 can be electrically connected between reference node 272 and ground rail 298 and can generate (i.e., can be configured to generate) a second reference current (Iref2). Iref2 can, for example, be generated in response to a second control signal (CS2) and can be less than Iref1. For example, in some embodiments, Iref2 can be generated in response to CS2 such that it is equal to approximately one half of Iref1 (e.g., such that it is equal to approximately 0.1*Icell_max). In some embodiments, as illustrated in sense circuit 195B of FIG. 2B, this second reference current source 240 can be an N-type field effect transistor (NFET). The NFET can include: N+ source/drain regions 241-242; a P-channel region or an intrinsic channel region between the N+ source/drain regions 241-242; and a gate 245 adjacent to the channel region. Gate 245 can be electrically connected to receive CS2 (e.g., from control signal generator 280, discussed in greater detail below). Alternatively, any other now known or subsequently developed second reference current source could be employed. The reference section of sense circuit 195A, 195B can further include a second capacitor 262. Second capacitor 262 can include: capacitor plates that are electrically connected to reference node 272 and ground rail 298; and a capacitor dielectric between the capacitor plates. The first and second capacitors 261-262 can exhibit essentially the same capacitances. The reference section of sense circuit 195A, 195B can further include a second switch 264, which is electrically connected between second positive supply voltage rail 201 at VDD1 (i.e., Vpre-charge) and reference node 272.

Referring again to FIGS. 1 and 2A-2B, within an NVM structure 100, including a sense circuit 195 (e.g., a sense circuit 195A or 195B, as described above and illustrated in FIG. 2A or 2B, respectively), a read operation of a selected bit cell 101 can include, for example, concurrently closing and re-opening first and second switches 263 and 264 so that data node 271 and reference node 272 are pre-charged to Vpre-charge (via second positive supply voltage rail 201). The read operation can further include electrically connecting the BL for the column containing the selected bit cell 101 to data node 271 (e.g., via MUX 120 and DL). Then, concurrently, a read word line voltage (VWLread) can be applied to the WL for the row containing the selected bit cell 101, CS1 can be applied to first reference current source 230, and CS2 can be applied to second reference current source 240. As a result, Icell will be generated by the selected bit cell 101, Iref1 will be generated by first reference current source 230, and Iref2 will be generated by the second reference current source 240. Given VWLread and depending upon whether the VT-programmable NFET of the selected bit cell 101 has been programmed so as to have a high VT (e.g., to store a bit value of 0) or erased so as to have a low VT (e.g., to store a bit value of 1), Icell through the selected bit cell 101 will be relatively low or relatively high, respectively. As a result of both the variable Icell and Iref1 being injected into data node 271, Vdata at inverting input 251 of comparator 250 will either ramp up above Vpre-charge (if the VT-programmable NFET has a high VT) or ramp down below Vpre-charge (if the VT-programmable NFET has a low VT). Additionally, as a result of Iref2 being pulled out of reference node 272, Vref at non-inverting input 252 of comparator 250 will ramp down below Vpre-charge (but to a lesser extent than Vdata when the VT-programmable NFET has a low VT). Following a predetermined time period (again referred to herein as tsense) after the read operation has been initiated and Vdiff0 or Vdiff1 have had sufficient time to develop, the comparator 250 can be enabled. As mentioned above, when the comparator is enabled, it can compare Vdata to Vref and: (a) if Vdata is above Vref and the first predetermined voltage differential (Vdiff0) is detected, then Dout at output 255 will switch to a logic value of 0; and (b) if Vdata is below Vref and the second predetermined voltage differential (Vdiff1) is detected, then Dout at output 255 will switch to a logic value of 1. However, by causing Vref to ramp down below Vpre-charge instead of remaining constant at Vpre-charge during the read operation, tsense (i.e., the time period between when the read operation is initiated and when the comparator can be enabled) can be reduced (e.g., by up to 50%) without risking read errors.

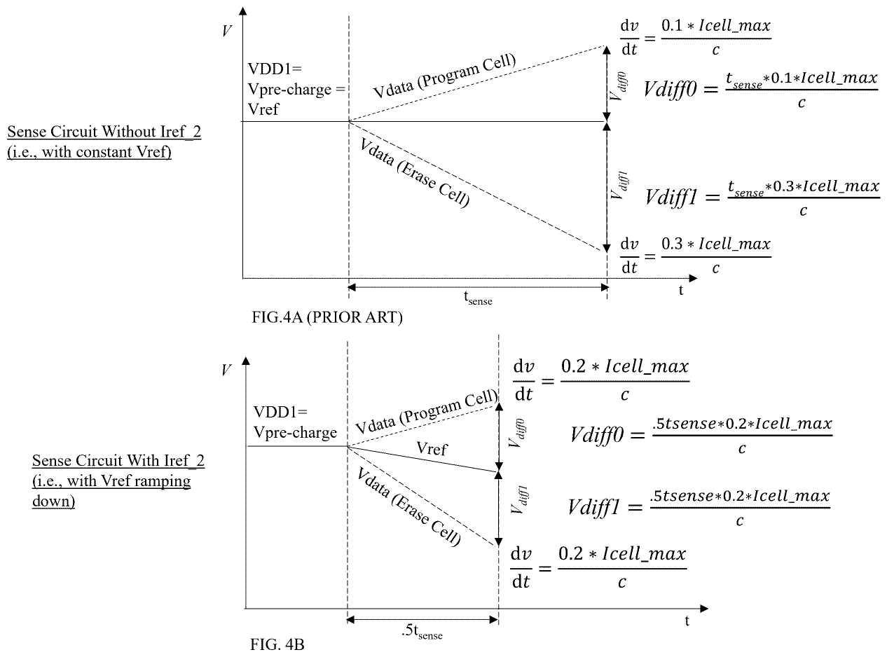

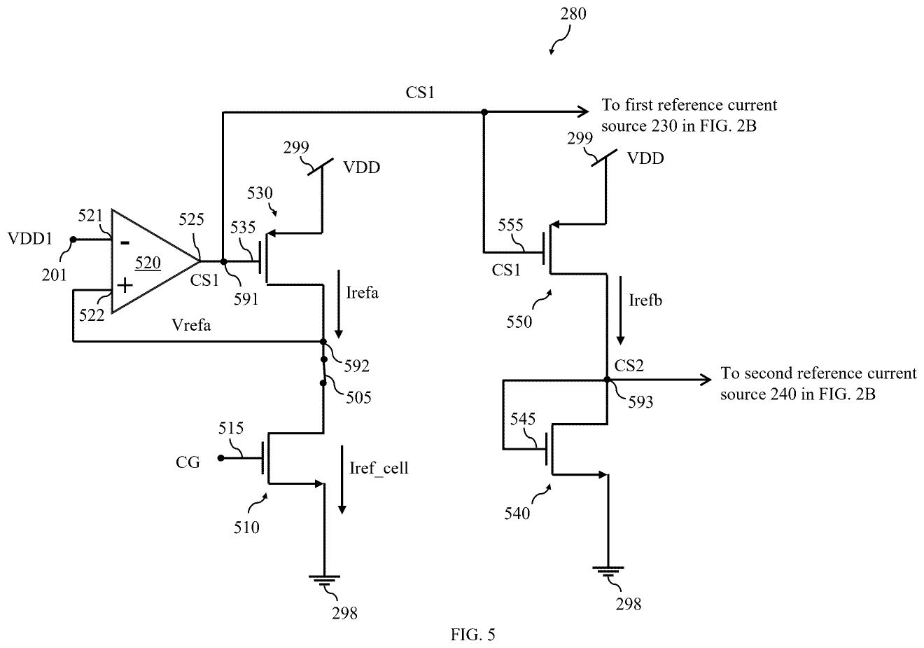

For example, FIG. 4A is a graph illustrating operation of a conventional sense circuit that is devoid of a second reference current source 240 within the reference section. More particularly, FIG. 4A illustrates: Vref remaining constant at Vpre-charge; Vdata ramping up above Vref when the VT-programmable NFET of a selected bit cell is programmed (i.e., has a high VT) and the resulting Vdiff0 over time; Vdata ramping down below Vref when the VT-programmable NFET of a selected bit cell is erased (i.e., has a low VT) and the resulting Vdiff1 over time; and the tsense required to develop a high enough Vdiff0 or Vdiff1 to avoid read errors. As illustrated in FIG. 4A, the limiting factor on tsense is Vdiff0 because Vdata rises at a relatively slow rate when the VT-programmable NFET is programmed, whereas Vdata drops at a relatively fast rate when the VT-programmable NFET is erased.

FIG. 4B is a graph illustrating operation of disclosed embodiments of a sense circuit (e.g., as illustrated in FIGS. 2A and 2B) that include second reference current source 240 within the reference section. More particularly, FIG. 4B illustrates: Vref ramping down below Vpre-charge; Vdata ramping up above Vref when the VT-programmable NFET of a selected bit cell is programmed (i.e., has a high VT) and the resulting Vdiff0 over time; Vdata ramping down below Vref when the VT-programmable NFET of a selected bit cell is erased (i.e., has a low VT) and the resulting Vdiff1 over time; and the tsense required to develop a high enough Vdiff0 or Vdiff1 to avoid read errors. As illustrated in FIG. 4B, although Vdata still ramps up at a relatively slow rate when the VT-programmable NFET of the selected bit cell is programmed (i.e., has a high VT), the tsense required to develop a high enough Vdiff0 is reduced because Vref is concurrently ramping down. Furthermore, while the rate at which Vdiff1 increases is not as fast as in FIG. 4A, the reduced tsense is still sufficient to achieve a Vdiff1 high enough to avoid read errors. In some embodiments, tsense can be reduced by up to 50% and this reduction in tsense can result in an overall reduction in read access time (tacc) by up to 30% or more. Furthermore, increase in total area consumption associated with the improved sense circuit can be less than 1%.

As mentioned above, CS1 and CS2 are employed to control the first and second reference current sources 230 and 240 in sense circuit 195B of FIG. 2B and can be generated by a control signal generator 280. FIG. 5 is a schematic diagram illustrating one example of such a control signal generator 280. As illustrated in FIG. 5, control signal generator 280 can be configured, for example, as a local current mirror circuit.

Specifically, control signal generator 280 can include a first pair of transistors. The first pair of transistors can include a PFET 530 and an NFET 510, which are series-connected between the first positive supply voltage rail 299 and the ground rail 298. NFET 510 in the first pair of transistors can be a reference bit cell. For example, NFET 510 can be a VT-programmable NFET with essentially the same configuration as the VT-programmable NFETs of the bit cells 101. Although not shown, NFET 510 can optionally be a selected one of multiple reference bit cells connectable to PFET 530 via a switch 505. In any case, gate 515 of NFET 510 can be electrically connected to receive an additional control voltage (CG) (which is equal to the read word line voltage (VWLread) concurrently applied to the WL connected to the selected bit cell 101 during the read operation). Thus, NFET 510 can generate a reference cell current (Iref_cell) that is equal to 0.2*Icell_max.

Control signal generator 280 can further include a second pair of transistors. The second pair of transistors can include a PFET 550 and an NFET 540, which are also series-connected between the first positive supply voltage rail 299 and the ground rail 298. The PFET 550 of the second pair can be smaller than the PFET 530 of the first pair (e.g., PFET 550 can be one half the size of PFET 530).

Control signal generator 280 can further include an additional comparator 520 (e.g., an additional operational amplifier). This additional comparator 520 can include: an inverting input 521, which is electrically connected to the second positive supply voltage rail 201 to receive the second positive supply voltage (VDD1); a non-inverting input 522; and an output 525. Additional comparator 520 can be configured to generate and output CS1 at output 525. Output 525 can further be electrically connected to first reference current source 230 and, particularly, gate 235 thereof in sense circuit 195B of FIG. 2B.

Control signal generator 280 can further include a first intermediate node 591, a second intermediate node 592, and a third intermediate node 593. First intermediate node 591 can be electrically connected to the output 525 of additional comparator 520 to receive CS1. Second intermediate node 592 can be located at the junction (i.e., on the interconnect) between PFET 530 and NFET 510 in the first pair of transistors. Third intermediate node 593 can be located at the junction (i.e., on the interconnect) between PFET 550 and NFET 540 in the second pair of transistors.

Within this control signal generator 280, gates 535 and 555 of PFETs 530 and 550, respectively, can be electrically connected to first intermediate node 591 and, thereby to output 525 of additional comparator 520 to receive CS1. Thus, PFET 530 can generate a first additional reference current (Irefa) in response to CS1 and Irefa can be equal to Iref1. For example, in some embodiments, Iref1 (and thereby Irefa) can be approximately equal to 0.2*Icell_max. Additionally, PFET 550 can generate a second additional reference current (Irefb) in response to CS1 and, given the smaller size of PFET 550, Irefb be smaller than Irefa and, more particularly, equal to Iref2. In some embodiments, Iref2 (and thereby Irefb) can be approximately equal to 0.1*Icell_max.

Additionally, within this control signal generator 280, the non-inverting input 522 of additional comparator 520 can be electrically connected to second intermediate node 592. Thus, the non-inverting input 522 can receive a first feedback voltage (Vrefa) generated on second intermediate node 592 given both Irefa and Iref_cell. If VDD1 is above Vrefa, then CS1 will go low, thereby increasing Irefa and Irefb. If VDD1 is below Vrefa, then CS1 will go high, thereby decreasing Irefa and Irefb.

Finally, within this control signal generator 280, the gate 545 of NFET 540 can be electrically connected to third intermediate node 593. Additionally, CS2 can be generated on the third intermediate node 593 given Irefb. The third intermediate node 593 can be electrically connected to second reference current source 240 and, particularly, to gate 245 thereof in sense circuit 195B of FIG. 2B.

It should be noted that, given the control signal generator 280, as described above and illustrated in FIG. 5, and the first and second reference current sources 230 and 240, as described above and illustrated in FIG. 2B, the relationships between Icell_max, Iref1, and Iref2 in sense circuit 195B of FIG. 2B can be essentially maintained across process and temperature variations.

It should be understood that in the method and structures described above, a semiconductor material refers to a material whose conducting properties can be altered by doping with an impurity. Exemplary semiconductor materials include, for example, silicon-based semiconductor materials (e.g., silicon, silicon germanium, silicon germanium carbide, silicon carbide, etc.) and III-V compound semiconductors (i.e., compounds obtained by combining group III elements, such as aluminum (Al), gallium (Ga), or indium (In), with group V elements, such as nitrogen (N), phosphorous (P), arsenic (As) or antimony (Sb)) (e.g., GaN, InP, GaAs, or GaP). A pure semiconductor material and, more particularly, a semiconductor material that is not doped with an impurity for the purposes of increasing conductivity (i.e., an undoped semiconductor material) is referred to in the art as an intrinsic semiconductor. A semiconductor material that is doped with an impurity for the purposes of increasing conductivity (i.e., a doped semiconductor material) is referred to in the art as an extrinsic semiconductor and will be more conductive than an intrinsic semiconductor made of the same base material. That is, extrinsic silicon will be more conductive than intrinsic silicon; extrinsic silicon germanium will be more conductive than intrinsic silicon germanium; and so on. Furthermore, it should be understood that different impurities (i.e., different dopants) can be used to achieve different conductivity types (e.g., P-type conductivity and N-type conductivity) and that the dopants may vary depending upon the different semiconductor materials used. For example, a silicon-based semiconductor material (e.g., silicon, silicon germanium, etc.) is typically doped with a Group III dopant, such as boron (B) or indium (In), to achieve P-type conductivity, whereas a silicon-based semiconductor material is typically doped with a Group V dopant, such as arsenic (As), phosphorous (P) or antimony (Sb), to achieve N-type conductivity. A gallium nitride (GaN)-based semiconductor material is typically doped with magnesium (Mg) to achieve P-type conductivity and with silicon (Si) or oxygen to achieve N-type conductivity. Those skilled in the art will also recognize that different conductivity levels will depend upon the relative concentration levels of the dopant(s) in a given semiconductor region.

It should be understood that the terminology used herein is for the purpose of describing the disclosed structures and methods and is not intended to be limiting. For example, as used herein, the singular forms “a,” “an,” and “the” are intended to include the plural forms as well, unless the context clearly indicates otherwise. Additionally, as used herein, the terms “comprises,” “comprising,” “includes,” and/or “including” specify the presence of stated features, integers, steps, operations, elements, and/or components, but do not preclude the presence or addition of one or more other features, integers, steps, operations, elements, components, and/or groups thereof. Furthermore, as used herein, terms such as “right,” “left,” “vertical,” “horizontal,” “top,” “bottom,” “upper,” “lower,” “under,” “below,” “underlying,” “over,” “overlying,” “parallel,” “perpendicular,” etc., are intended to describe relative locations as they are oriented and illustrated in the drawings (unless otherwise indicated) and terms such as “touching,” “in direct contact,” “abutting,” “directly adjacent to,” “immediately adjacent to,” etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element. The corresponding structures, materials, acts, and equivalents of all means or step plus function elements in the claims below are intended to include any structure, material, or act for performing the function in combination with other claimed elements as specifically claimed.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various disclosed embodiments have been presented for purposes of illustration but are not intended to be exhaustive or limiting. Many modifications and variations will be apparent to those of ordinary skill in the art without departing from the scope and spirit of the disclosed embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
a comparator including an inverting input and a non-inverting input;
a data node connected to the inverting input;
a reference node connected to the non-inverting input;
a first reference current source connected between a first positive supply voltage rail and the data node; and
a second reference current source connected between the reference node and a ground rail.

2. The structure of claim 1,
wherein the first reference current source generates a first reference current, and
wherein the second reference current source generates a second reference current that is less than the first reference current.

3. The structure of claim 2, wherein the second reference current is one half the first reference current.

4. The structure of claim 2, further comprising:
a first capacitor connected between the data node and the ground rail; and
a second capacitor connected between the reference node and the ground rail, wherein the first capacitor and the second capacitor exhibit approximately equal capacitances.

5. The structure of claim 2, further comprising:
a first switch connected between a second positive supply voltage rail and the data node; and
a second switch between the second positive supply voltage rail and the reference node.

6. The structure of claim 5, further comprising: a data line connected between a
multiplexer and the data node,
wherein a selected bit cell in an array of bit cells is connectable through the multiplexer and the data line to the data node during a read operation,
wherein the selected bit cell includes a threshold voltage-programmable transistor programmable to a high threshold voltage state to store a bit value of 0 and erasable to a low threshold voltage state to store a bit value of 1, and
wherein, during the read operation, the data node and the reference node are pre-charged to a pre-charge voltage through the first switch and the second switch, respectively, and a gate of the threshold voltage-programmable transistor receives an additional control signal, and
wherein, during the read operation, when the selected bit cell stores the bit value of 0, the first reference current causes a data voltage on the data node to rise above the pre-charge voltage, and when the selected bit cell stores the bit value of 1, the data voltage on the data node drops below the pre-charge voltage.

7. The structure of claim 6, wherein, during the read operation, the second reference current causes a reference voltage on the reference node to drop below the pre-charge voltage.

8. A structure comprising:
a comparator including an inverting input and a non-inverting input;
a data node connected to the inverting input;
a reference node connected to the non-inverting input;
a first reference current source including a P-type field effect transistor connected between a first positive supply voltage rail and the data node;
a second reference current source including an N-type field effect transistor connected between the reference node and a ground rail; and
a sense circuit control signal generator generating and outputting a first control signal and a second control signal, wherein a gate of the P-type field effect transistor is connected to receive the first control signal and a gate of the N-type field effect transistor is connected to receive the second control signal.

9. The structure of claim 8,
wherein the P-type field effect transistor generates a first reference current in response to the first control voltage, and
wherein the N-type field effect transistor generates a second reference current that is less than the first reference current in response to the second control voltage.

10. The structure of claim 9, wherein the second reference current is one half the first reference current.

11. The structure of claim 9, further comprising:
a first capacitor connected between the data node and the ground rail; and
a second capacitor connected between the reference node and the ground rail, wherein the first capacitor and the second capacitor exhibit approximately equal capacitances.

12. The structure of claim 9, further comprising:
a first switch connected between a second positive supply voltage rail and the data node; and
a second switch connected between the second positive supply voltage rail and the reference node.

13. The structure of claim 12, further comprising: a data line connected between a
multiplexer and the data node,
wherein a selected bit cell in an array of bit cells is connectable through the multiplexer and the data line to the data node during a read operation,
wherein the selected bit cell includes a threshold voltage-programmable transistor programmable to a high threshold voltage state to store a bit value of 0 and erasable to a low threshold voltage state to store a bit value of 1, and
wherein, during the read operation, the data node and the reference node are pre-charged to a pre-charge voltage through the first switch and the second switch, respectively, and a gate of the threshold voltage-programmable transistor receives an additional control signal, and
wherein, during the read operation, when the selected bit cell stores the bit value of 0, the first reference current causes a data voltage on the data node to rise above the pre-charge voltage, and when the selected bit cell stores the bit value of 1, the data voltage on the data node drops below the pre-charge voltage.

14. The structure of claim 13, wherein, during the read operation, the second reference current causes a reference voltage on the reference node to drop below the pre-charge voltage.

15. The structure of claim 13, wherein the sense circuit control signal generator includes:
a first pair of transistors;
a second pair of transistors, wherein the first pair and the second pair each include P-type and N-type field effect transistors series-connected between the first positive supply voltage rail and the ground rail, and wherein the P-type field effect transistor of the second pair is smaller than the P-type field effect transistor of the first pair;
an additional comparator including: an inverting input connected to the second positive supply voltage rail; a non-inverting input; and an output, wherein the additional comparator generates and outputs the first control signal at the output;
a first intermediate node connected to the output to receive the first control signal;
a second intermediate node at a junction between the P-type and N-type field effect transistors in the first pair; and
a third intermediate node at a junction between the P-type and N-type field effect transistors in the second pair,
wherein gates of the P-type field effect transistors of the first pair and the second pair are connected to the first intermediate node to receive the first control signal,
wherein the non-inverting input of the additional comparator is connected to the second intermediate node,
wherein a gate of the N-type field effect transistor of the first pair is connected to receive an additional control voltage,
wherein a gate of the N-type field effect transistor of the second pair is connected to the third intermediate node, and
wherein the second control signal is generated and output at the third intermediate node.

16. The structure of claim 15, wherein the sense circuit control signal generator further includes an additional switch connected between the second intermediate node and the N-type field effect transistor of the first pair, and wherein the N-type field effect transistor is a reference bit cell.

17. A structure comprising:
an array of bit cells arranged in columns and rows;
bit lines for the columns, wherein all bit cells in a column are connected to a bit line for the column;
a multiplexor having inputs connected to the bit lines and an output connected to a data line; and
a sense circuit including;
a comparator including an inverting input and a non-inverting input;
a data node connected to the data line and the inverting input;
a reference node connected to the non-inverting input;
a first reference current source connected between a first positive supply voltage rail and the data node; and
a second reference current source connected between the reference node and a ground rail.

18. The structure of claim 17,
wherein the first reference current source generates a first reference current, and
wherein the second reference current source generates a second reference current that is less than the first reference current.

19. The structure of claim 18, wherein the second reference current is one half the first reference current.

20. The structure of claim 18, further comprising:
a first capacitor connected between the data node and the ground rail;
a second capacitor connected between the reference node and the ground rail, wherein the first capacitor and the second capacitor exhibit approximately equal capacitances;
a first switch connected between a second positive supply voltage rail and the data node; and
a second switch between the second positive supply voltage rail and the reference node.
